(19) United States
(12) Patent Application Publication
(10) Pub. No.: US 2024/0266241 A1
(43) Pub. Date: Aug. 8, 2024

(54) SEMICONDUCTOR DEVICE

(71) Applicant: FUJI ELECTRIC CO., LTD., Kawasaki-shi (JP)

(72) Inventor: Sota YAMAGUCHI, Kawasaki-shi (JP)

(73) Assignee: FUJI ELECTRIC CO., LTD., Kawasaki-shi (JP)

(21) Appl. No.: 18/398,896

(22) Filed: Dec. 28, 2023

(30) Foreign Application Priority Data
Feb. 8, 2023 (JP) 2023-017431

(51) Int. Cl. H01L 23/367

(52) U.S. Cl. CPC H01L 23/367; H01L 24/32; H01L 25/072; H01L 2224/32225; H01L 2924/10253; H01L 2924/10272; H01L 2924/1033; H01L 2924/13055; H01L 2924/13091

(57) ABSTRACT

A semiconductor device includes a substrate, a semiconductor element on the substrate, and a cooler that cools the substrate, wherein the cooler includes a cooling body having a first part, and a second part protruding from the first part toward the substrate, and a cooling fin fixed within the second part, the cooling fin being exposed to an exterior of the device on a side thereof facing away from the substrate.

### BACKGROUND OF THE INVENTION

### 1. Technical Field

The present invention relates to a semiconductor device including a substrate provided with a semiconductor element and a cooler that cools the substrate.

### 2. Description of the Related Art

A conventional semiconductor device includes a substrate provided with a semiconductor element, such as an insulated gate bipolar transistor (IGBT). As such a type of semiconductor device, there is a known semiconductor device including a cooling fin and a water jacket having a path for cooling water that passes the cooling fin, integrated together (for example, refer to JP 2022-065238 A or JP 2020-027891 A).

### SUMMARY OF THE INVENTION

There is an open fin type of semiconductor device including a cooling fin exposed outward, in which a path for cooling water is disposed at an external device, such as an inverter. Such an open fin type of semiconductor device has no bottom disposed below the cooling fin fixed to a top. Thus, the exposed cooling fin is likely to be damaged in manufacturing or in conveying. If an additional member such as a reinforcing member is disposed on the upper face of the peripheral edge of the top, an increase is made in the height of the semiconductor device.

An object of the present invention is to provide a semiconductor device that is low in height and enables prevention of an outward exposed cooling fin from being damaged.

According to an aspect, provided is a semiconductor device including: a substrate provided with a semiconductor element; and a cooler that cools the substrate, in which the cooler includes: a top including a protrusion protruding toward the substrate; and a cooling fin that is fixed inside the protrusion and is exposed outside on a side opposite to the substrate.

According to the aspect, the semiconductor device is low in height and enables prevention of the cooling fin exposed outward from being damaged.

### BRIEF DESCRIPTION OF THE DRAWINGS

FIG. 1 is a plan view of a schematic configuration of a semiconductor device according to an embodiment;

FIG. 2 is a sectional view taken along line II-II of FIG. 1;

FIG. 3 is a perspective view of a top in an embodiment;

FIG. 4 is an exploded perspective view of the top and a reinforcing member in an embodiment;

FIG. 5 is an exploded perspective view of a top and a reinforcing member in a first modification of an embodiment;

FIG. 6 is a sectional view taken along line VI-VI of FIG. 5;

FIG. 7 is an exploded perspective view of a top and a reinforcing member in a second modification of an embodiment;

FIG. 8 is an exploded perspective view of a top and a reinforcing member in a third modification of an embodiment;

FIG. 9 is a right side view of a top and a cooling fin in a fourth modification of an embodiment;

FIG. 10 is a right side view of a top and a cooling fin in a fifth modification of an embodiment;

FIG. 11 is a right side view of a top and a cooling fin in a sixth modification of an embodiment;

FIG. 12 is a right side view of a top and a cooling fin in a seventh modification of an embodiment; and

FIG. 13 is a right side view of a top and a cooling fin in an eighth modification of an embodiment.

### DETAILED DESCRIPTION

A semiconductor device according to an embodiment of the present invention will be described below with reference to the drawings. Note that the present invention is not limited to the following embodiment and thus appropriate modifications can be made without departing from the gist of the present invention.

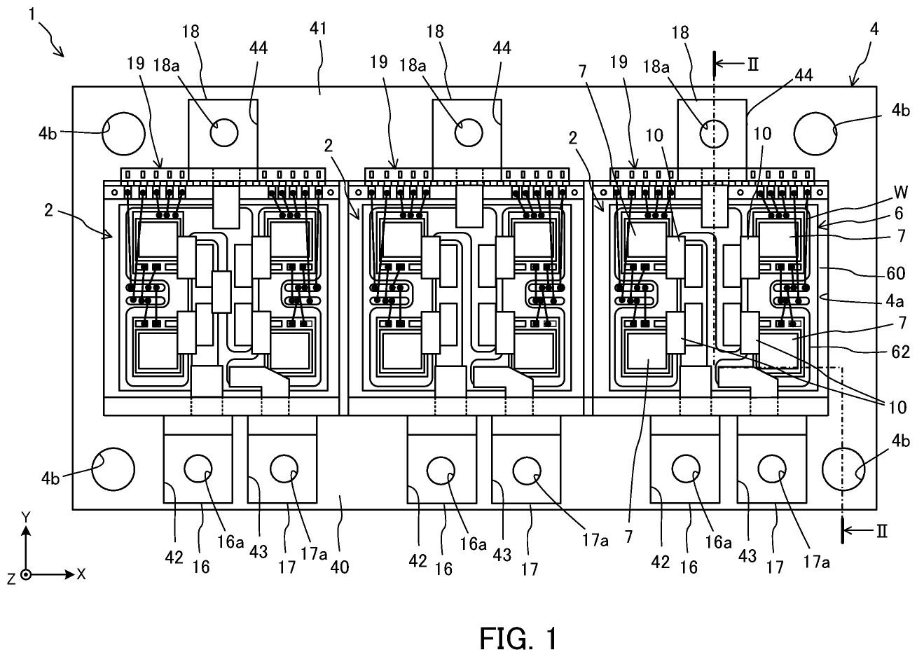

FIG. 1 is a plan view of a schematic configuration of a semiconductor device 1 according to an embodiment.

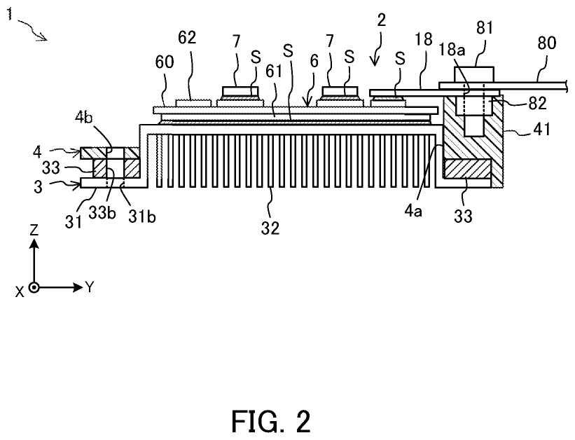

FIG. 2 is a sectional view taken along line II-II of FIG. 1.

Note that, from among X, Y, and Z directions indicated in FIGS. 1 and 2 and FIGS. 3 to 13 to be described later, the Z direction is defined as the up-down direction of the semiconductor device 1 (thickness direction of an insulating substrate 6). The X and Y directions orthogonal to the Z direction are defined, respectively, as the longitudinal direction of the semiconductor device 1 and the lateral direction of the semiconductor device 1, respectively. In some cases, the X, Y, and Z directions are referred to as front-rear, left-right, and up-down directions, respectively. Such directional terms are used for convenience of description. Thus, depending of the posture of attachment of the semiconductor device 1, the correspondence relationship with the X, Y, and Z directions varies.

The semiconductor device 1 according to the present embodiment is applied, for example, to a power converter, such as a power control unit, and serves as a power semiconductor module for an inverter circuit.

The semiconductor device 1 illustrated in FIGS. 1 and 2 includes three unit modules 2, a cooler 3 that cools the unit modules 2 (refer to FIG. 2), a case 4 that houses the unit modules 2, and sealing resin (not illustrated) injected in the case 4.

The unit modules 2 each include an insulating substrate 6 and semiconductor elements 7 disposed on the insulating substrate 6. The insulating substrate 6 is an exemplary substrate provided with semiconductor elements 7. In the present embodiment, the three unit modules 2 are disposed side by side in the X direction. The three unit modules 2 achieve, for example, U, V, and W phases, resulting in formation of a three-phase inverter circuit. Note that the unit modules 2 may be each referred to as a power cell or semiconductor unit. The number of unit modules 2 to be disposed is at least one.

As illustrated in FIG. 2, the insulating substrate 6 is achieved, for example, with a direct copper bonding (DCB) substrate, an active metal brazing (AMB) substrate, or a metal base substrate. For example, the insulating substrate 6 includes an insulator 60, a heat dissipator 61 disposed on the lower face of the insulator 60, and a plurality of circuit plates 62 disposed on the upper face of the insulator 60. For example, the insulating substrate 6 is rectangular in shape in plan view.

For example, the insulator 60 is formed of an insulating material, such as a ceramic material (e.g., alumina (Al₂O₃), aluminum nitride (AlN), or silicon nitride (Si₃N₄)), a resin material (e.g., epoxy), or an epoxy resin material with a ceramic material as a filler. Note that the insulator 60 may be referred to as an insulating layer or insulating film.

The heat dissipator 61 has a predetermined thickness in the Z direction and is formed on the lower face of the insulator 60. For example, the heat dissipator 61 is formed of metal favorable in thermal conductivity, such as copper or aluminum. For example, favorably, the heat dissipator 61 is joined to the cooler 3 through a binder, such as solder S, simultaneously with or after joining of components, such as the semiconductor elements 7, to the insulating substrate 6 through solder S and before sealing resin is injected into the case 4.

The insulator 60 has the plurality of circuit plates 62 on its upper face. The number of circuit plates 62 on the upper face of the insulator 60 may be at least one. The circuit plates 62 each correspond to a metal layer, such as copper leaf, and are insular in mutually electrical isolation on the insulator 60. Note that the circuit plates 62 may be each referred to as a circuit layer.

As illustrated in FIG. 2, the semiconductor elements 7 are disposed through solder S on the upper face of the insulating substrate 6 (circuit plates 62). Referring to FIG. 1, four semiconductor elements 7 are indicated per single insulating substrate 6, but the number of semiconductor elements 7 can be freely selected. For example, the semiconductor elements 7 are each achieved with a semiconductor substrate based on silicon (Si), silicon carbide (SiC), gallium nitride (GaN), or diamond, and are each square or rectangular in shape in plan view.

Note that, as each semiconductor element 7, a switching element, such as an IGBT or a power MOSFET, and a diode, such as an FWD, are used. Such a switching element and a diode may be made in antiparallel connection. As each semiconductor element 7, used may be a reverse conducting (RC)-IGBT element of an IGBT and an FWD in unification, a power MOSFET element, or a reverse blocking (RB)-IGBT element highly resistant to a reverse bias.

The semiconductor elements 7 are each made in electrically conductive connection with a predetermined circuit plate 62 through a metal wiring plate 10. For example, the metal wiring plate 10 is made of a metal material, such as copper material, copper-alloy-based material, aluminum-alloy-based material, or iron-alloy-based material, and is formed due to folding by pressing. For example, each semiconductor element 7 and the corresponding metal wiring plate 10 are joined together through a binder, such as solder. The metal wiring plates 10 may be referred to as a lead frame. Note that, instead of each metal wiring plate 10, a connector, such as a conductive wire, may be disposed.

The case 4 is shaped like a rectangular frame and has an opening 4a at its center. The three unit modules 2 described above are housed in the opening 4a rectangular in shape. That is, the three unit modules 2 are housed in the space demarcated by the case 4 shaped like a frame.

As illustrated in FIG. 1, the case 4 is provided with main terminals (P terminals 16, N terminals 17, and M terminals 18) each as an exemplary external connecting terminal for external connection and control terminals 19 for control. Regarding walls 40 and 41 paired and opposed in the lateral direction (Y direction) of the case 4, the wall 40 located on the negative side in the Y direction (on the lower side of FIG. 1) has recesses 42 and 43 each rectangular in shape in plan view.

The recesses 42 each have a P terminal 16 disposed therein. A single P terminal 16 is disposed per single unit module 2. For example, preferably, each P terminal 16 is joined on a circuit plate 62 through an ultrasonic welded portion (not illustrated).

Similarly, the recesses 43 each have an N terminal 17 disposed therein. A single N terminal 17 is disposed per single unit module 2. For example, similarly to the P terminals 16, preferably, each N terminal 17 is joined on a circuit plate 62 through an ultrasonic welded portion (not illustrated).

Regarding the walls 40 and 41 paired and opposed in the lateral direction (Y direction) of the case 4, the wall 41 on the positive side in the Y direction (on the upper side of FIG. 1) has recesses 44 each rectangular in shape in plan view. The recesses 44 each have an M terminal 18 disposed therein. A single M terminal 18 is disposed per single unit module 2. For example, similarly to the P terminals 16 and the N terminals 17, preferably, each M terminal 18 is joined on a circuit plate 62 through an ultrasonic welded portion (not illustrated).

The P terminals 16 may be each referred to as a positive terminal (input terminal). The N terminals 17 may be each referred to as a negative terminal (output terminal). The M terminals 18 may be each referred to as an intermediate terminal (output terminal). Each P terminal 16 has an end jointed to a circuit plate 62 as described above and has the other end provided with a screw hole 16a. Each N terminal 17 has an end joined to a circuit plate 62 as described above and has the other end provided with a screw hole 17a. Each M terminal 18 has an end joined to a circuit plate 62 as described above and has the other end provided with a screw hole 18a. Thus, the P terminals 16, the N terminals 17, and the M terminals 18 each serve as a main terminal connectable to an external conductor (refer to an external conductor 80 illustrated in FIG. 2). Note that, in the example of FIG. 2, the external conductor 80 is fixed to the case 4 by a bolt 81 and a nut 82 with the screw hole 18a of the M terminal 18.

The wall 41 on the positive side in the Y direction of the case 4 is provided with the control terminals 19. For example, ten control terminals 19 are disposed per single unit module 2. More specifically, in each single unit module 2, the M terminal 18 is interposed, in the left-right direction (X direction), between five control terminals 19 and the other five control terminals 19 from among the ten control terminals 19. The ten control terminals are disposed along the outer circumference of the opening 4a. Note that the shape of each control terminal 19, the location at which each control terminal 19 is disposed, and the number of control terminals 19 to be disposed are not limited to the above, and thus appropriate modifications can be made.

For example, each control terminal 19 is formed of a metal material, such as copper material, copper-alloy-based material, aluminum-alloy-based material, or iron-alloy-based material. For example, the control terminals 19 are embedded in the case 4 by integrated molding (insert molding) and are each connected to a portion of the corresponding unit module 2 through a wiring member W (may be referred to as a control wired line). As the wiring member W, a conductive wire (bonding wire) is used. As the material of such a conductive wire, one of gold, copper, aluminum, a gold alloy, a copper alloy, and an aluminum alloy or any combination thereof can be used. As the wiring member, a member different from any conductive wires can be used. For example, a ribbon can be used as the wiring member.

The case 4 has a plurality of through holes 4b along its outer peripheral edge. For example, the through holes 4b each serve as a hole for insertion of a screw for fixing the semiconductor device 1 and an external device such as an inverter (not illustrated) together. Note that, preferably, the case 4 and the cooler 3 are fixed together through pins (not illustrated).

Note that, for example, as resin for the case 4, any insulating resin can be selected from polyphenylene sulfide (PPS), polybutylene terephthalate (PBT), polybutyl acrylate (PBA), polyamide (PA), acrylonitrile butadiene styrene (ABS), a liquid crystal polymer (LCP), polyether ether ketone (PEEK), polybutylene succinate (PBS), urethane, and silicone. Resin to be selected may be a mixture of two or more types of resin. Such resin may contain a filler (e.g., a glass filler) for improvement in strength or functionality.

The sealing resin (not illustrated) injected in the inner space prescribed by the case 4 shaped like a frame seals the space in which the insulating substrates 6 and the semiconductor elements 7 mounted on the insulating substrates 6 are located. The sealing resin is achieved with a thermosetting resin. Preferably, the sealing resin contains at least one of epoxy, silicone, urethane, polyimide, polyamide, and a polyamide-imide. As the sealing resin, for example, an epoxy resin containing a filler is preferable because of its insulation, heat resistance, and heat dissipation.

As illustrated in FIG. 2, the cooler 3 includes a top (cooling body) 31 that has a first part and a second part (protrusion) 31a, a cooling fin 32, and a reinforcing member 33, and cools the insulating substrates 6. For example, preferably, at least two of the top 31, the cooling fin 32, and the reinforcing member 33 are made of the same metal material (e.g., aluminum).

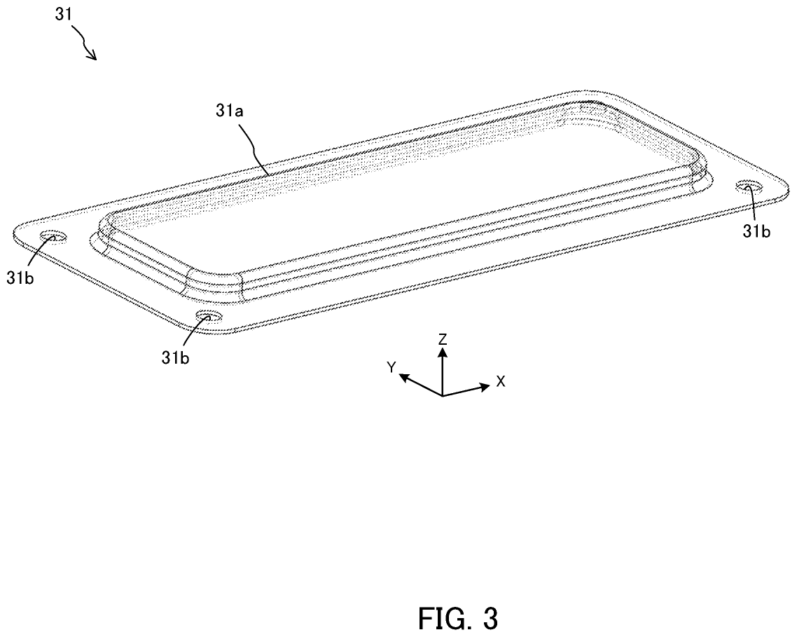

As illustrated in FIG. 3, the protrusion 31a protrudes from the first part of the top 31 toward the insulating substrates 6, and the first part has a plate shape parallel to the circuit plate 62 and surrounds an outer periphery of the protrusion 31a. The protrusion 31a is joined to the heat dissipator 61 of each insulating substrate 6 through solder S, for example. The top 31 has screw holes 31b at positions corresponding to four through holes 4b of the case 4 described above. In the example of FIG. 1, the case 4 is provided with four through holes 4b. If the case 4 is provided with through holes 4b of which the number is more than four, the number of screw holes 31b to be disposed to the top 31 and the number of screw holes 33b to be disposed to the reinforcing member 33 to be described later are made identical to the number of through holes 4b. Note that the level of protrusion of the protrusion 31a toward the insulating substrates 6 is, for example, approximately 5 to 6 mm.

The cooling fin 32 illustrated in FIG. 2 is fixed inside the top 31 (on the inner upper face of the top 31) and is exposed outside on the side opposite to the insulating substrates 6 (on the lower side). As above, the cooler 3 does not have any member, such as a bottom, below the cooling fin 32 such that the cooling fin 32 is exposed outside (on the side opposite to the insulating substrates 6). Thus, the cooler 3 (semiconductor device 1) in the present embodiment can be referred to as an open fin type.

Regarding this open fin type of cooler 3, a path for cooling water (exemplary coolant) that passes the cooling fin 32 is disposed at the external device (e.g., the inverter) to which the semiconductor device 1 is fixed.

The cooling fin 32 includes, for example, a plurality of pins, and preferably the entirety in the longitudinal direction (up-down direction) of each pin is housed inside the protrusion 31a. For example, the cooling fin 32 may be a forged fin or machined fin integrally formed with the top 31.

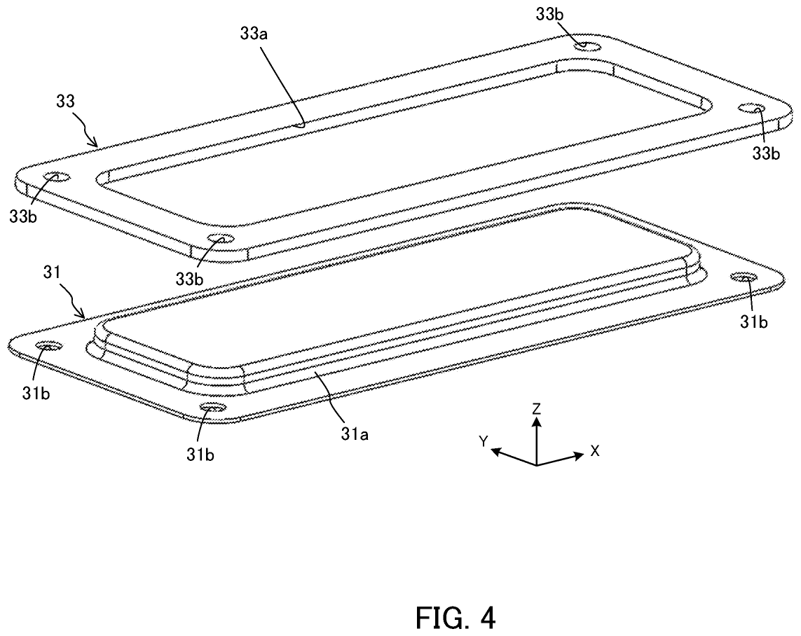

The reinforcing member 33 is an exemplary reinforcer and is disposed independently of the top 31. The reinforcing member 33 is located around the protrusion 31a of the top 31. For example, the reinforcing member 33 is joined to the upper face of the portion (flange) around the protrusion 31a of the top 31 by adhesion. As illustrated in FIG. 4, for example, the reinforcing member 33 is shaped like a rectangular frame and has, at its center, a rectangular through hole 33a for insertion of the protrusion 31a. As above, preferably, the reinforcing member 33 is shaped like a frame and is located along the entire circumference of the protrusion 31a.

The reinforcing member 33 has screw holes 33b at positions corresponding to the screw holes 31b of the top 31. Note that, for positioning between the reinforcing member 33 and the top 31, for example, preferably, the top 31 is mounted on a stage having positioning pins such that the positioning pins are inserted through the screw holes 31b, and then the reinforcing member 33 is mounted on the top 31 such that the positioning pins are inserted through the screw holes 33b, followed by adhesion (joining) of the top 31 and the reinforcing member 33.

For example, in a case where the top 31 has a thickness thicker at the portion (flange) around the protrusion 31a than at the protrusion 31a (831a) like an eighth modification to be described later (refer to FIG. 13), a thicker portion (831c) functions as a reinforcer. In this case, an increase can be inhibited in thermal resistance at the protrusion 31a (831a), in comparison to a case where the top 31 including the protrusion 31a is thick in thickness over all. In the present embodiment and the modification, as a reinforcer, the thicker portion (831c) may be used, instead of the reinforcing member 33.

Note that, although the arrangement of the reinforcer (reinforcing member 33 or thicker portion 831c of a top 831) can be omitted, desirably, the reinforcing member 33 (reinforcer) is disposed at least between the through holes 4b of the case 4 and the screw holes 31b of the top 31 since screws for fixing the semiconductor device 1 and the external device such as the inverter (not illustrated) are particularly inserted through the through holes 4b of the case 4. In a case where the reinforcing member 33 is disposed as a reinforcer, the reinforcing member 33 may be partially enhanced in strength to have a thickness thicker at portions corresponding to the through holes 4b of the case 4. The inner edge of the reinforcing member 33 (portion along the through hole 33a) may be provided with an upward projection extending upward along the protrusion 31a. Note that, for example, the thickness of the reinforcing member 33 is approximately half of the level of protrusion of the protrusion 31a toward the insulating substrates 6 (for example, the thickness of the reinforcing member 33 is not more than 3 mm, provided that the level of protrusion of the protrusion 31a is approximately 5 to 6 mm).

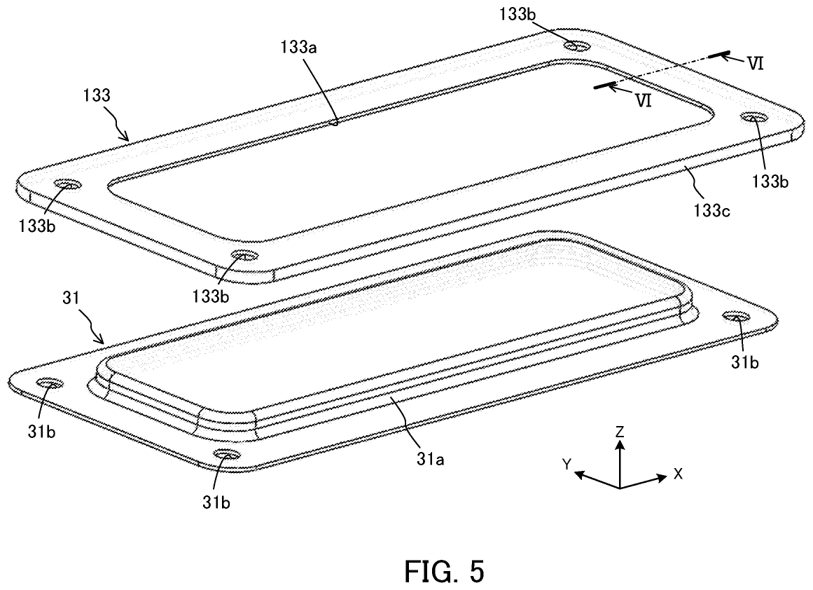

Next, first to eighth modifications of the present embodiment will be described with reference to FIGS. 5 to 13.

FIG. 5 is an exploded perspective view of a top 31 and a reinforcing member 133 in the first modification.

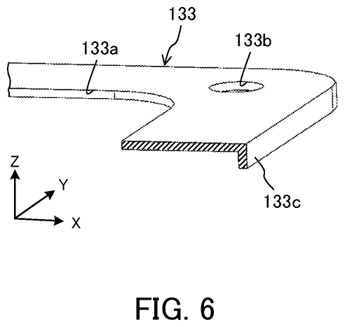

FIG. 6 is a sectional view taken along line VI-VI of FIG. 5.

In the present first modification, the reinforcing member 133 is different from the reinforcing member 33 illustrated in FIG. 4. Except for the difference, a semiconductor device 1 in the present first modification is similar to the semiconductor device 1 described above. For example, the reinforcing member 133 is shaped like a rectangular frame thinner than the reinforcing member 33 and has a through hole 133a and screw holes 133b identical to the through hole 33a and the screw holes 33b of the reinforcing member 33. As illustrated in FIG. 6 (in the sectional view taken along line VI-VI of FIG. 5), the reinforcing member 133 includes, along its peripheral edge, a bent portion 133c bent to the side opposite to insulating substrates 6 (to the lower side). For example, the bent portion 133c extends downward such that the leading end of the bent portion 133c is lower than the lower end of the top 31.

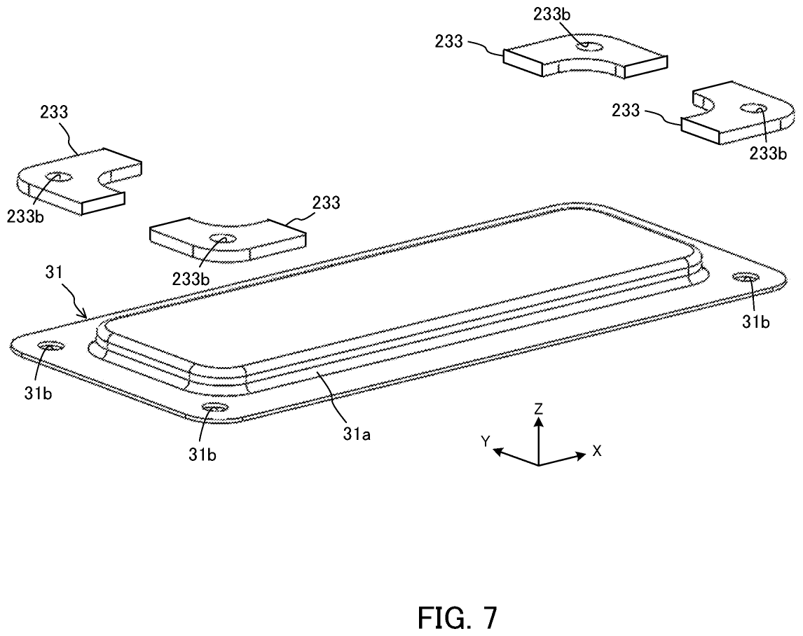

Note that, instead of the bent portion 133c bent to the side opposite to the insulating substrates 6 (to the lower side), the reinforcing member 133 may include a bent portion bent toward the insulating substrates 6 (to the upper side). The bent portion 133c of the reinforcing member 133 does not necessarily range over the entire peripheral edge and thus may be located, for example, at part of the peripheral edge (e.g., at two mutually opposed sides or at four sides without the corners). FIG. 7 is an exploded perspective view of a top 31 and a reinforcing member 233 in the second modification.

In the present second modification, the reinforcing member 233 is different from the reinforcing member 33 illustrated in FIG. 4. Except for the difference, a semiconductor device 1 in the present second modification is similar to the semiconductor device 1 described above. As illustrated in FIG. 7, the reinforcing member 233 has four parts. The parts of the reinforcing member 233 each have a screw hole 233b. The screw holes 233b of the parts are identical in position to the four screw holes 33b of the reinforcing member 33. For example, preferably, the space between each part of the reinforcing member 233 is filled by downward extension of such a case 4 as illustrated in FIG. 2. Note that the number of parts of the reinforcing member 233 is not limited to four and thus may be at least two. Since the parts of the reinforcing member 233 are spaced apart from each other, the reinforcing member 233 is less in the quantity of material than the reinforcing member 33 illustrated in FIG. 4.

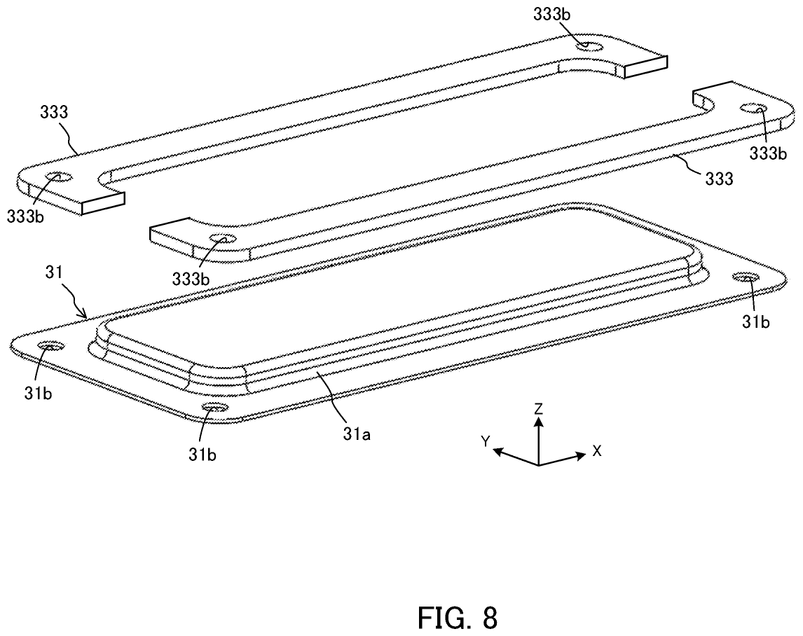

FIG. 8 is an exploded perspective view of a top 31 and a reinforcing member 333 in the third modification of an embodiment.

In the present third modification, the reinforcing member 333 is different from the reinforcing member 33 illustrated in FIG. 4. Except for the difference, a semiconductor device 1 in the present third modification is similar to the semiconductor device 1 described above. As illustrated in FIG. 8, the reinforcing member 333 has two parts. The parts of the reinforcing member 333 each have two screw holes 333b, and the screw holes 333b of the parts are identical in position to the four screw holes 33b of the reinforcing member 33. Note that, since the parts of the reinforcing member 333 are separated from each other at the center in the lateral direction (Y direction) of the top 31 from the X and Y directions orthogonal to the thickness direction (Z direction) of the top 31, each part has a C shape (U shape) of which the longitudinal direction is identical to the longitudinal direction (X direction) of the top 31. Note that the parts of the reinforcing member 333 may be separated from each other at the center in the longitudinal direction (X direction) of the top 31 such that each part has a C shape (U shape).

FIG. 9 is a right side view of a top 31 and a cooling fin 432 in the fourth modification.

In the present fourth modification, the cooling fin 432 is different from the cooling fin 32 illustrated in FIG. 2. Except for the difference, a semiconductor device 1 in the present fourth modification is similar to the semiconductor device 1 described above. As illustrated in FIG. 9, part of the cooling fin 432 projects from inside a protrusion 31a (indicated with a dotted line), and the other part is housed in the protrusion 31a. Note that, even in a case where the cooling fin 432 projects from inside the protrusion 31a, preferably, the cooling fin 432 is housed, by half or more in the longitudinal direction (up-down direction), inside the protrusion 31a.

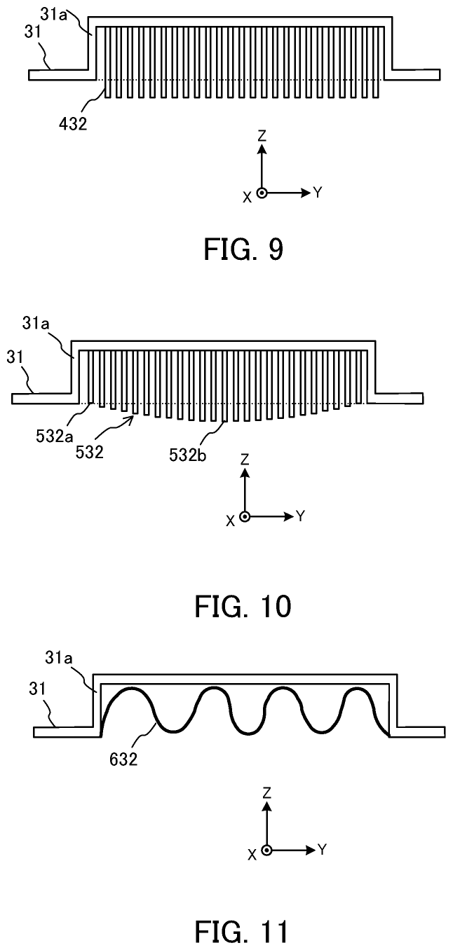

FIG. 10 is a right side view of a top 31 and a cooling fin 532 in the fifth modification.

In the present fifth modification, the cooling fin 532 is different from the cooling fin 32 illustrated in FIG. 2. Except for the difference, a semiconductor device 1 in the present fifth modification is similar to the semiconductor device 1 described above. As illustrated in FIG. 10, the cooling fin 532 includes an outer fin 532a located on its outside (on its outside in the X direction and Y direction) inside a protrusion 31a. The entirety in the longitudinal direction (up-down direction) of the outer fin 532a is housed inside the protrusion 31a. In addition, the cooling fin 532 includes an inner fin 532b located on its inside (at its center in the X direction and Y direction) inside the protrusion 31a. Part of the inner fin 532b projects from inside the protrusion 31a (indicated with a dotted line) and the other part is housed in the protrusion 31a.

The cooling fin 532 includes a plurality of fins including the outer fin 532a and the inner fin 532b, and fins closer to the center of the protrusion 31a have leading end located lower. Even in such a case where fins, closer to the center of the protrusion 31a, in the cooling fin 532 have leading ends located lower as above, the entirety in the longitudinal direction (up-down direction) of all the fins of the cooling fin 532 may be housed inside the protrusion 31a. Note that the outer fin 532a is likely to be damaged easier than the inner fin 532b in the cooling fin 532 in manufacturing or in conveying and thus at least the outer fin 532a is housed inside the protrusion 31a, so that the cooling fin 532 can be prevented from being damaged.

FIG. 11 is a right side view of a top 31 and a cooling fin 632 in the sixth modification.

In the present sixth modification, the cooling fin 632 is different from the cooling fin 32 illustrated in FIG. 2. Except for the difference, a semiconductor device 1 in the present sixth modification is similar to the semiconductor device 1 described above. As illustrated in FIG. 11, the cooling fin 632 serves as a corrugated fin sinuous in shape and is, for example, made of a metal material. As above, the cooling fin 632 is different from a fin including a plurality of pins. Note that, similarly to the cooling fins 432 and 532 illustrated in FIGS. 9 and 10, respectively, the cooling fin 632 may partially project from inside a protrusion 31a, but preferably the entirety thereof is housed inside the protrusion 31a.

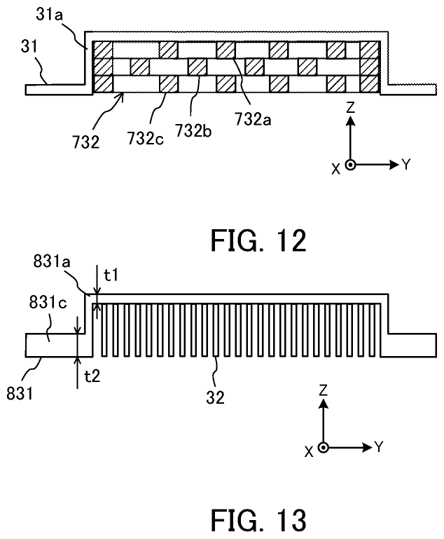

FIG. 12 is a right side view of a top 31 and a cooling fin 732 in the seventh modification.

In the present seventh modification, the cooling fin 732 is different from the cooling fin 32 illustrated in FIG. 2. Except for the difference, a semiconductor device 1 in the present seventh modification is similar to the semiconductor device 1 described above. As illustrated in FIG. 12, the cooling fin 732 includes an upper layer fin 732a, an intermediate layer fin 732b, and a lower layer fin 732c stacked one on another. As above, the cooling fin 732 serves as a stack fin including a plurality of plates having a plurality of through holes corresponding to a path for cooling water. Note that, similarly to the cooling fins 432 and 532 as illustrated in FIGS. 9 and 10, respectively, the cooling fin 732 may partially project from inside a protrusion 31a, but preferably the entirely thereof is housed inside the protrusion 31a.

FIG. 13 is a right side view of a top 831 and a cooling fin 732 in the eighth modification.

In the present eighth modification, the top 831 is different from the top 31 illustrated in FIG. 2. Except for the difference, a semiconductor device 1 in the present eighth modification is similar to the semiconductor device 1 described above. As illustrated in FIG. 13, the top 831 has a thickness thicker at a thicker portion 831c as the portion (flange) around a protrusion 831a (thickness t2) than at the protrusion 831a (thickness t1) (t2>t1). The thicker portion 831c is an exemplary reinforcer located around the protrusion 831a and is disposed instead of the reinforcing member 33 described above. Note that the thicker portion 831c may be provided at a plurality of positions, such as places for fastening with screws for fixing the semiconductor device 1 and an external device together (through holes 4b of a case 4) or may be shaped like a frame and be provided along the entire circumference of the protrusion 831a.

According to the present embodiment described above, a semiconductor device 1 includes insulating substrates 6 (exemplary substrates) each provided with semiconductor elements 7 and a cooler 3 that cools the insulating substrates 6. The cooler 3 includes a top 31 including a protrusion 31a protruding toward the insulating substrates 6 (e.g., to the upper side) and a cooling fin 32 that is fixed inside the protrusion 31a and is exposed outside on the side opposite to the insulating substrates 6 (e.g., on the lower side).

As above, since the cooling fin 32 is fixed inside the protrusion 31a of the top 31, the cooling fin 32 can be prevented from being damaged in manufacturing or in conveying, in comparison to an aspect in which the cooling fin 32 is fixed to the lower face of a top tabular in shape and the entirety of the cooling fin 32 is exposed outside. Since the top 31 is provided with the protrusion 31a, a space for a member, such as a reinforcing member 33, to be disposed can be secured on the side opposite to the side of location of a path for cooling water of the top 31 (e.g., on the side of location of the insulating substrates 6, namely, on the upper side) or a space for fixing an external conductor 80 (e.g., a space for such a bolt 81 as illustrated in FIG. 2) can be secured around the protrusion 31a. Thus, an increase can be prevented in the height of the cooler 3, leading to prevention of an increase in the height of the semiconductor device 1. Therefore, according to the present embodiment, the semiconductor device 1 is low in height and enables prevention of the cooling fin 32 exposed outside from being damaged.

In the present embodiment, the cooler 3 further includes a reinforcing member 33 (133, 233, 333) as an exemplary reinforcer located around the protrusion 31a.

Thus, for example, even when the reinforcing member 33 is disposed at places for fastening with screws for fixing the semiconductor device 1 and an external device together (through holes 4b of a case 4), an increase can be prevented in the height of the cooler 3, leading to prevention of an increase in the height of the semiconductor device 1. Since the reinforcing member 33 is disposed around the protrusion 31a, an enhancement in the strength of the top 31 (cooler 3) can be made on the side opposite to the path for cooling water at the external device, such as an inverter (on the side of location of the insulating substrates 6, namely, on the upper side). Thus, in comparison to an aspect in which the reinforcing member 33 is disposed on the side of location of the path for cooling water (on the lower side) of the top 31, there is no risk of water leakage and there is no need to manage process design based on water leakage.

In the present embodiment, the reinforcing member 33 (133) is shaped like a frame and is located along the entire circumference of the protrusion 31a.

Thus, for example, the reinforcing member 33 as a single item can be disposed at a plurality of places to be reinforced, such as the through holes 4b of the case 4, so that a reduction can be made in the number of components and the reinforcing member 33 is attached easily, in comparison to an aspect in which the reinforcing member 233 or 333 including a plurality of parts is disposed. In addition, an enhancement can be made in the strength of the reinforcing member 33.

In the present embodiment, the reinforcing member 133 illustrated in FIGS. 5 and 6 includes a bent portion 133c that is located along its peripheral edge and is bent to the side opposite to the insulating substrates 6 (or to the side of location of the insulating substrates 6).

Thus, an enhancement can be made in the strength of the reinforcing member 133. In a case where the bent portion 133c of the reinforcing member 133 is bent to the side opposite to the insulating substrates 6, positioning with the top 31 can be carried out with the bent portion 133c.

In the present embodiment, a reinforcer located around the protrusion 31a corresponds to the reinforcing member 33 disposed independently of the top 31.

Thus, the disposed reinforcing member 33 serves, for example, as a reinforcer provided easily with no change in the thickness of the top 31.

In the present embodiment, a reinforcer located around a protrusion 831a corresponds to a thicker portion 831c with which a top 831 is provided.

Thus, in comparison to a case where the reinforcing member 33 is disposed, a reduction can be made in the number of components and assembly can be facilitated without positioning between the top 31 and the reinforcing member 33.

In the present embodiment, the entirety of the cooling fin 32 (632, 732) is housed inside the protrusion 31a.

Thus, the cooling fin 32 can be further prevented from being damaged in manufacturing or in conveying.

The invention in the claims in the present application will be noted below.

### Note 1

A semiconductor device including:
a substrate provided with a semiconductor element; and
a cooler that cools the substrate, in which
the cooler includes
a top including a protrusion protruding toward the substrate, and
a cooling fin fixed inside the protrusion, the cooling fin being exposed outside on a side opposite to the substrate.

### Note 2

The semiconductor device according to Note 1, in which
the cooler further includes a reinforcer located around the protrusion.

### Note 3

The semiconductor device according to Note 2, in which
the reinforcer is shaped like a frame and is located along an entire circumference of the protrusion.

### Note 4

The semiconductor device according to Note 2 or 3, in which
the reinforcer includes a bent portion located along a peripheral edge of the reinforcer, the bent portion being bent to the side opposite to the substrate or toward the substrate.

### Note 5

The semiconductor device according to Note 2 or 3, in which
the reinforcer includes a reinforcing member disposed independently of the top.

### Note 6

The semiconductor device according to Note 2 or 3, in which
the reinforcer includes a thicker portion with which the top is provided.

### Note 7

The semiconductor device according to Note 1, in which
entirety of the cooling fin is housed inside the protrusion.

As described above, the present invention has an effect of achieving a semiconductor device that is low in height and enables prevention of a cooling fin exposed outside from being damaged, and thus is valuable to, for example, a power semiconductor device.

What is claimed is:

1. A semiconductor device, comprising:
a substrate;
a semiconductor element on the substrate; and
a cooler that cools the substrate, wherein
the cooler includes
a cooling body having a first part, and a second part protruding from the first part toward the substrate, and
a cooling fin fixed within the second part, the cooling fin being exposed to an exterior of the device at a side thereof opposite to a side facing the substrate.

2. The semiconductor device according to claim 1, wherein the cooler further includes a reinforcer on the first part and around the second part.

3. The semiconductor device according to claim 2, wherein the reinforcer has a frame shape that entirely surrounds a circumference of the second part.

4. The semiconductor device according to claim 2, wherein the reinforcer has a bent portion along a peripheral edge thereof, the bent portion being bent toward or away from the substrate.

5. The semiconductor device according to claim 2, wherein the reinforcer includes a reinforcing member that is independent of the first part.

6. The semiconductor device according to claim 2, wherein the reinforcer is a portion of first part having a thickness greater than a thickness of the rest of the first part.

7. The semiconductor device according to claim 1, wherein the cooling fin comprises a plurality of cooling fins entirely housed within the second part.
